(19) United States
(12) Patent Application Publication
(10) Pub. No.: US 2006/0018351 A1
(43) Pub. Date: Jan. 26, 2006

(54) Semiconductor laser device

(75) Inventors: Kazunori Matsubara, Nara-ken (JP); Takeshi Horiguchi, Higashihiroshima-shi (JP); Hideshi Koizumi, Higashihiroshima-shi (JP)

Correspondence Address: NIXON & VANDERHYE, PC, 901 NORTH GLEBE ROAD, 11TH FLOOR, ARLINGTON, VA, 22203, US

(73) Assignee: SHARP KABUSHIKI KAISHA, Osaka (JP)

(21) Appl. No.: 11/185,838

(22) Filed: Jul. 21, 2005

(30) Foreign Application Priority Data
Jul. 22, 2004 (JP) P2004-214266

(51) Int. Cl. H01S 5/00; H01S 3/04

(52) U.S. Cl. 372/43.01; 372/36; 372/50.21

(57) ABSTRACT

In a semiconductor laser device, a wiring board (101) has pad patterns on its top surface, on which a block (102) is also mounted. The block (102) has a first mounting surface (113) and a second mounting surface (114), both of which face in an identical direction. The block (102) also has a raising mirror (111) for changing an optical axis of light. On the first mounting surface (113) is mounted a semiconductor laser element (103) which emits laser light (L). On the second mounting surface (114) is mounted a light receiving element (104) which receives reflected light of the laser light (L).

This nonprovisional application claims priority under 35 U.S.C. §119(a) on Patent Application No. 2004-214266 filed in Japan on 22 Jul. 2004, the entire contents of which are hereby incorporated by reference.

### BACKGROUND OF THE INVENTION

The present invention relates to a semiconductor laser device and an optical pickup device having the semiconductor laser device.

### BACKGROUND ART

Among optical pickup devices used for optical recording mediums such as CD-ROMs (Compact Disc Read Only Memories) and MDs (Mini Discs) to read signals therefrom, there is known an optical pickup device employing a semiconductor laser device according to a “hologram laser system”. The hologram laser system is a system that, with a semiconductor laser element, a holographic element, and a signal light receiving element incorporated in one package, a light beam is emitted from the semiconductor laser element and the light beam reflected and returned from the optical disc, which is an optical recording medium, is diffracted by the holographic element so as to be led to the light receiving element set at a place away from the optical axis.

An example of conventional semiconductor laser devices employing the hologram laser system is disclosed in JP 06-5990 A. This semiconductor laser device, as shown in FIG. 9A, includes a stem 1, a cap 5 placed on the stem 1, and a holographic element 6 placed on the cap 5. The stem 1 is provided with a plurality of leads 7. The stem 1 and the cap 5 are generally elliptical in their top shape for smaller thickness.

FIG. 9B shows a schematic perspective view of the semiconductor laser device from which the cap 5 and the holographic element 6 have been removed.

A block 2 integrally molded with the stem 1 has a semiconductor laser element 3 and a light receiving element 4 mounted thereon. That is, as shown in FIG. 9C, the semiconductor laser element 3 is fixed to a side face 13 of the block 2, and the light receiving element 4 is fixed to a top face 14 of the block 2.

Further, the semiconductor laser element 3 and the light receiving element 4 are connected to end faces of the leads 7 exposed from the top face of the stem 1 via wires 9. Thus, electric currents can be fed to the semiconductor laser element 3 by using the leads 7, and a detection signal of the light receiving element 4 can be extracted outside.

However, in this semiconductor laser device, since the semiconductor laser element 3 is fixed to the side face 13 of the block 2 and the light receiving element 4 is fixed to the top face 14 of the block 2, there arises a need for mounting operations from two directions to the block 2. Accordingly, manufacturing processes related to the mounting of the semiconductor laser element 3 and the light receiving element 4 become more complex, which eventually causes a drawback of increased manufacturing costs related to their mounting.

In the above semiconductor laser device, with a plurality of through-holes provided in the stem 1, after insertion of the leads 7 into the through-holes one by one, clearances between the through-holes and the leads 7 are filled with an insulator. Because of this, a manufacturing process related to the packaging is complex, which also disadvantageously increases the manufacturing cost.

### SUMMARY OF THE INVENTION

Accordingly, an object of the present invention is to provide a semiconductor laser device which allows a semiconductor laser element and a light receiving element to be surface mounted on a block from one direction and which can also eliminate the use of a stem-and-lead structure to thereby reduce the manufacturing cost, and also to provide an optical pickup device having such a semiconductor laser device.

In order to accomplish the above object, a semiconductor laser device according to the present invention comprises:
a wiring board having wiring patterns on at least one surface thereof;
a block mounted on the one surface of the wiring board, the block having first and second mounting surfaces both facing in an identical direction, and including a mirror part for changing an optical axis of light;
a semiconductor laser element mounted on the first mounting surface and emitting laser light; and
a first light receiving element mounted on the second mounting surface and receiving reflected light of the laser light.

In this semiconductor laser device, since the first mounting surface to carry the semiconductor laser element and the second mounting surface to carry the light receiving element face in the same direction, the semiconductor laser element and the light receiving element can be surface mounted on the block from one direction. Accordingly, a manufacturing process related to the mounting of the semiconductor laser element and the light receiving element is simplified. This allows a reduction in manufacturing cost of the semiconductor laser device to be achieved.

Further, by the block being mounted on one surface of the wiring board, the wiring patterns of the wiring board are electrically connected to the semiconductor laser element and the light receiving element, so that an electric current can be fed to the semiconductor laser element via a wiring pattern while a signal detected by the light receiving element can be extracted outside via a wiring pattern. Accordingly, it is no longer necessary to use, for example, a stem-and-lead structure in the semiconductor laser device, so that a manufacturing process related to the packaging of the semiconductor laser device is simplified. This enables a further reduction in cost for manufacturing the semiconductor laser device.

In one embodiment, the mirror part changes the optical axis of light by about 90°.

In one embodiment, the wiring board includes a heat sink having through-holes, a first printed board placed on the heat sink, and a second printed board placed under the heat sink and connecting to the first printed board via the through-holes.

In one embodiment, the wiring board has a main body made of ceramics.

In one embodiment, the semiconductor laser device further includes a cap which covers the block, the semiconductor laser element and the light receiving element.

In one embodiment, the semiconductor laser device further includes a holographic element placed on the cap for leading the reflected light to the light receiving element.

In one embodiment, a far-field pattern of the semiconductor laser element is an ellipse whose major axis is inclined at an angle of about 45° with respect to the second mounting surface.

In one embodiment, the semiconductor laser device further includes a second light receiving element which the laser light partially enters.

In one embodiment, the mirror part is a half mirror part, and part of the laser light that has passed through the half mirror part enters the second light receiving element.

In one embodiment, the half mirror part has a polarization property.

In one embodiment, electrode portions of the semiconductor laser element and the light receiving element are connected to the wiring patterns via wires.

In one embodiment, the block is formed of an insulator.

An optical pickup device for performing reproduction, erasing, and/or recording of information on an optical disc, according to the present invention, includes:
the semiconductor laser device as described above;
a collimator lens placed in an optical path between the semiconductor laser device and the optical disc; and
an objective lens placed in an optical path between the collimator lens and the optical disc.

Because the optical pickup device includes the semiconductor laser device, it can be fabricated at a reduced cost.

In one embodiment, the first and second mounting surfaces are roughly parallel to a recording surface of the optical disc.

In one embodiment, the objective lens has a numerical aperture larger than a numerical aperture of the collimator lens.

### BRIEF DESCRIPTION OF THE DRAWINGS

The present invention will become more fully understood from the detailed description given hereinbelow and the accompanying drawings which are given by way of illustration only, and thus are not intended to limit the present invention, and wherein:

FIG. 1 is a schematic perspective view of a semiconductor laser device according to en embodiment of the present invention;

FIG. 2 is a schematic top view of the semiconductor laser device of FIG. 1;

FIG. 3A is a schematic side view of a wiring board of the semiconductor laser device of FIG. 1;

FIG. 3B is a schematic bottom view of the wiring board;

FIGS. 4A to 4F are manufacturing process diagrams of the semiconductor laser device of FIG. 1;

FIG. 5A is a schematic side view of an optical pickup device according to en embodiment of the invention;

FIG. 5B is a schematic bottom view of the optical pickup device;

FIGS. 6A to 6D are manufacturing process diagrams of a semiconductor laser device according to another embodiment of the invention;

FIG. 7A is a schematic perspective view of a block of the semiconductor laser device of FIG. 1;

FIG. 7B is a view showing a general shape of a beam spot formed by a semiconductor laser element on the block of FIG. 7A;

FIG. 7C is a schematic perspective view of a block of a semiconductor laser device according to another embodiment of the present invention;

FIG. 7D is a view showing a general shape of a beam spot formed by a semiconductor laser element on the block of FIG. 7C;

FIG. 7E is a schematic perspective view of a block of a semiconductor laser device according to another embodiment of the present invention;

FIG. 7F is a view showing a general shape of a beam spot formed by a semiconductor laser element on the block of FIG. 7E;

FIG. 7G is a schematic perspective view of a block of a semiconductor laser device according to another embodiment of the present invention;

FIG. 7H is a view showing a general shape of a beam spot formed by a semiconductor laser element on the block of FIG. 7G;

FIG. 8 is a schematic sectional view of a semiconductor laser device according to still another embodiment of the invention;

FIG. 9A is a schematic perspective view of a prior art semiconductor laser device;

FIG. 9B is a schematic perspective view of the prior art semiconductor laser device from which the cap and the holographic element have been removed; and

FIG. 9C is a schematic perspective view of the prior art semiconductor laser device before a laser element and a light receiving element are mounted.

### DETAILED DESCRIPTION OF THE INVENTION

Hereinbelow, the semiconductor laser device and the optical pickup device having it according to the present invention will be described in detail by embodiments thereof illustrated in the accompanying drawings.

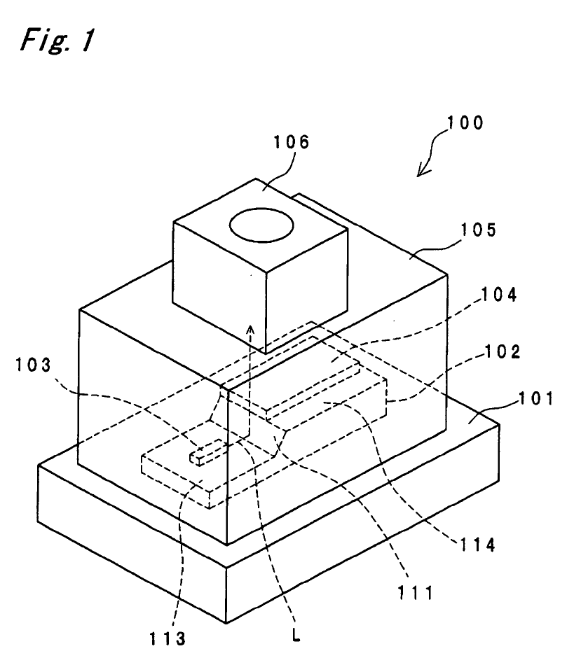

FIG. 1 is a schematic perspective view of a semiconductor laser device 100 according to an embodiment of the invention.

The semiconductor laser device 100 includes a wiring board 101, a block 102 mounted on a top face of the wiring board 101 as an example of the claimed one surface, a semiconductor laser element 103 which emits laser light L, a light receiving element 104 which receives reflected light of the laser light, a rectangular-parallelopiped cap 105 which covers the block 102, the semiconductor laser element 103 and the light receiving element 104, and a holographic element 106 which is placed on the cap 105. The block 102 is an example of the claimed block, and the light receiving element 104 is an example of the claimed first light receiving element.

The block 102, which is formed of an insulator, has a first mounting surface 113 on which the semiconductor laser element 103 is mounted, a second mounting surface 114 on which the light receiving element 104 is mounted, and a raising mirror 111 for reflecting the laser light L emitted by the semiconductor laser element 103. The raising mirror 111 is an example of the mirror part.

The first mounting surface 113 is generally parallel to the second mounting surface 114. That is, the first mounting surface 113 and the second mounting surface 114 are oriented in the same direction. Then, the first, second mounting surfaces 113, 114 are generally parallel to the top face of the wiring board 101.

The raising mirror 111 connects the first mounting surface 113 and the second mounting surface 114 to each other. Also, the raising mirror 111 is inclined at an angle of 45° with respect to an optical axis of the laser light L. As a result of this, the raising mirror 111 changes the direction of the optical axis of the laser light L by about 90°.

The holographic element 106 leads reflected light of the laser light to the light receiving element 104.

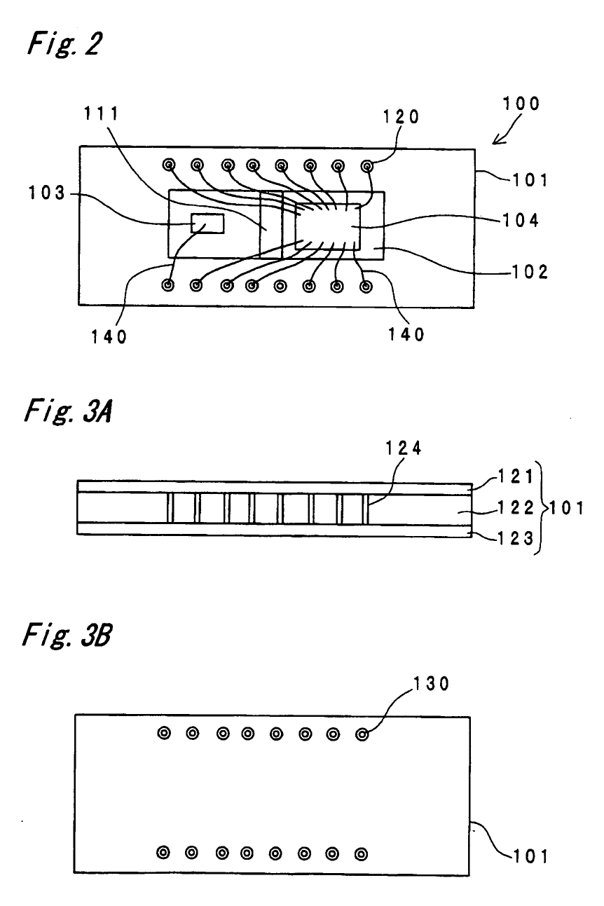

FIG. 2 is a schematic top view of the semiconductor laser device 100 in which the cap 105 and the holographic element 106 have been removed.

On the top of the wiring board 101 are provided pad patterns 120 as an example of the wiring patterns. The pad patterns 120 are electrically connected to input/output terminals (electrode portions) of the semiconductor laser element 103 and the light receiving element 104 via wires 140.

FIG. 3A is a schematic side view of the wiring board 101. FIG. 3B is a schematic bottom view of the wiring board 101.

The wiring board 101, as shown in FIG. 3A, has a three-layer structure consisting of a top-face printed board 121 as an example of a first printed board, a Cu (copper) plate 122, and a bottom-face printed board 123 as an example of the second printed board. The Cu plate 122 has through-holes 124 bored through the thickness of the Cu plate 122. These through-holes 124 are covered at their inner walls with an insulator, and filled with an electrical conductor placed inside of the insulator. The top-face printed board 121 is placed on the Cu plate 122, and the bottom-face printed board 123 is placed under the Cu plate 122. Then, as shown in FIG. 3B, the wiring board 101 is provided with a plurality of electrode portions 130 at specified intervals on its bottom face, i.e. on a bottom face of the bottom-face printed board 123. These electrode portions 130 and the pad patterns 120 are placed in a conducting state via the conductor within the through-holes 124. The Cu plate 122 is an example of the heat sink, and the electrode portions 130 are an example of the wiring patterns.

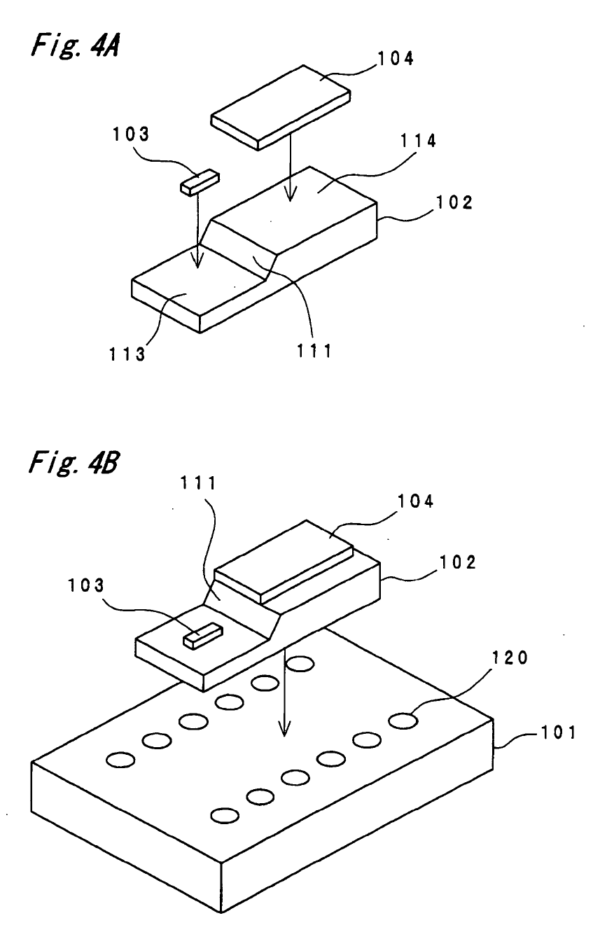

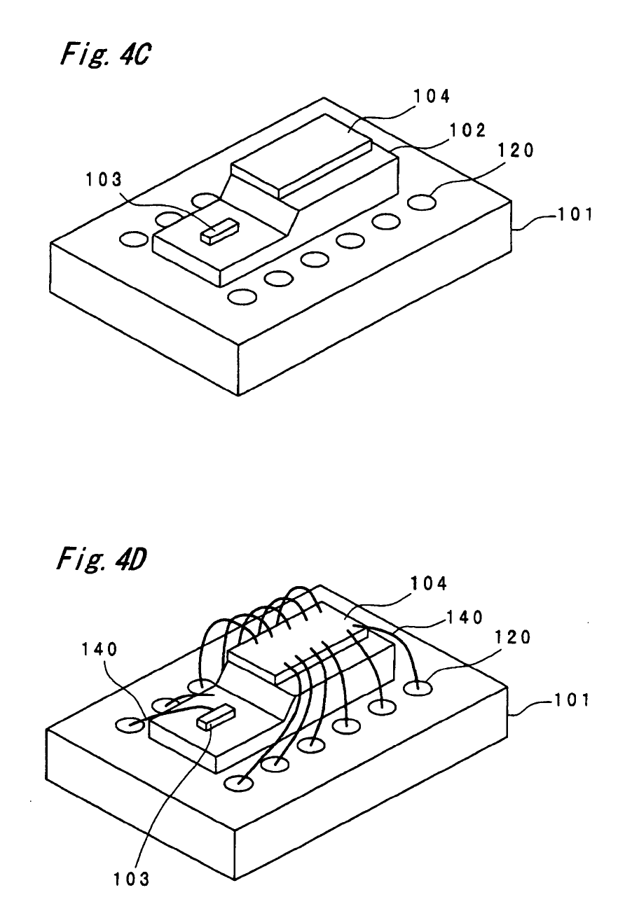

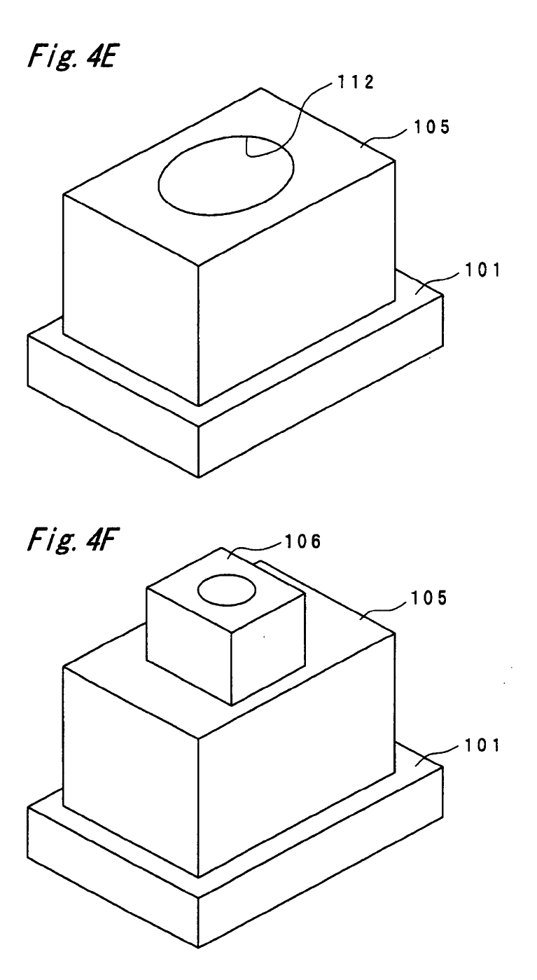

Now, the manufacturing process of the semiconductor laser device 100 will be described with reference to FIGS. 4A to 4F.

First, as shown in FIG. 4A, the semiconductor laser element 103 is mounted on the first mounting surface 113 of the block 102. The semiconductor laser element 103 is fixed to the first mounting surface 113 with a bond or a brazing material.

Next, the light receiving element 104 is mounted on the second mounting surface 114 of the block 102. The light receiving element 104 is fixed to the second mounting surface 114 also with a bond or a brazing material.

Next, as shown in FIG. 4B, the block 102 mounted with the semiconductor laser element 103 and the light receiving element 104 is mounted on top of the wiring board 101 with a bond or the like. Then, as shown in FIG. 4C, the pad patterns 120 are located on both sides of the block 102.

Next, a wire bonding process is performed, so that input/output terminals of the semiconductor laser element 103 and the light receiving element 104 are electrically connected to the pad patterns 120 via the wires 140 as shown in FIG. 4D.

Next, as shown in FIG. 4E, the generally rectangular-parallelopiped cap 105 is fitted to the wiring board 101 with a bond. As a result of this, the block 102, the semiconductor laser element 103, the light receiving element 104, the pad patterns 120 and the wires 140 are covered with the cap 105 (see FIG. 1). The cap 105 has, on its top, an opening 112 through which the laser light L passes.

Finally, as shown in FIG. 4F, the holographic element 106 is placed on the cap 103 so that the opening 112 of the cap 103 is closed by the holographic element 106. Thereafter, the holographic element 106 is fixed to the cap 105 with a bond.

As described above, the first mounting surface 113 to carry the semiconductor laser element 103 and the second mounting surface 114 to carry the light receiving element 104 are set to face in the same direction, so that the semiconductor laser element 103 and the light receiving element 104 are able to be surface mounted on the block 102 from one direction. Accordingly, the manufacturing process related to the mounting of the semiconductor laser element 103 and the light receiving element 104 is simplified, so that the manufacturing cost reduction is achievable.

Also, since the manufacturing process related to the mounting of the semiconductor laser element 103 and the light receiving element 104 is simplified, it is possible to improve the yield of the semiconductor laser devices 100.

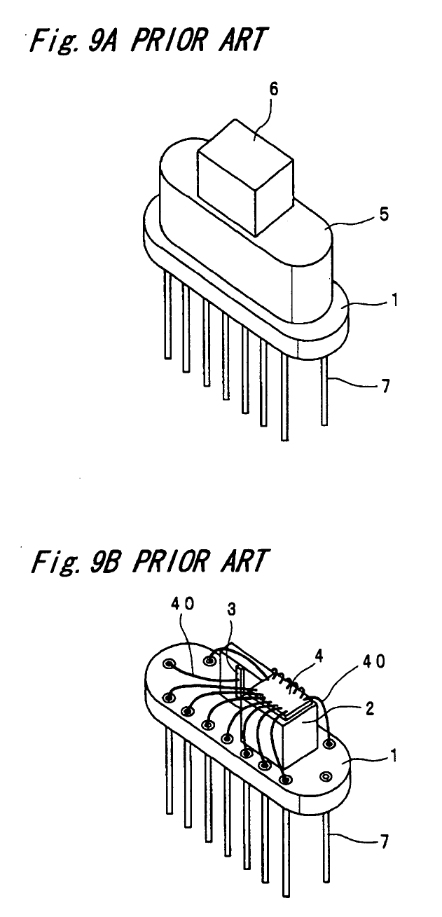

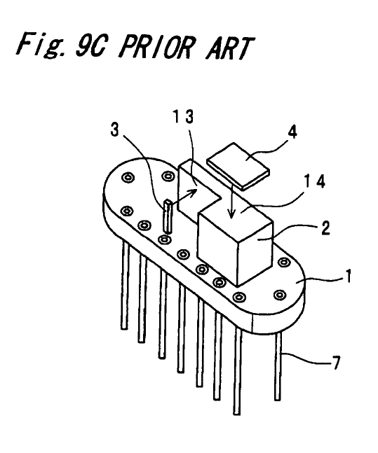

Further, by virtue of the mounting of the block 102 on the top face of the wiring board 101, electrically connecting the pad patterns 120 on the top face of the wiring board 101 to the semiconductor laser element 103 and the light receiving element 104 makes it possible to feed electric currents to the semiconductor laser element 103 via the pad patterns 120 and also to extract signals, which have been detected by the light receiving element 104, outside via the pad patterns 120. Accordingly, it is no longer necessary to use a structure having a stem and leads as shown in FIGS. 9A to 9C in the semiconductor laser device 100, so that manufacturing process steps related to the packaging are simplified. This also contributes to the manufacturing cost reduction.

Furthermore, because the wiring board 101 is structured such that the Cu plate 122 is sandwiched between the top-face printed board 121 and the bottom-face printed board 123, heat in the cap 105 is efficiently radiated outside via the Cu plate 122, so that the reliability of the semiconductor laser device 100 is assured. That is, by virtue of the Cu plate 122 of the wiring board 101, a good heat dissipation property and reliability of the semiconductor laser device 100 are obtainable.

A flexible board or the like may be joined to the bottom face of the wiring board 101 with a view to extracting signals detected by the light receiving element 104 to the outside via the pad patterns 120.

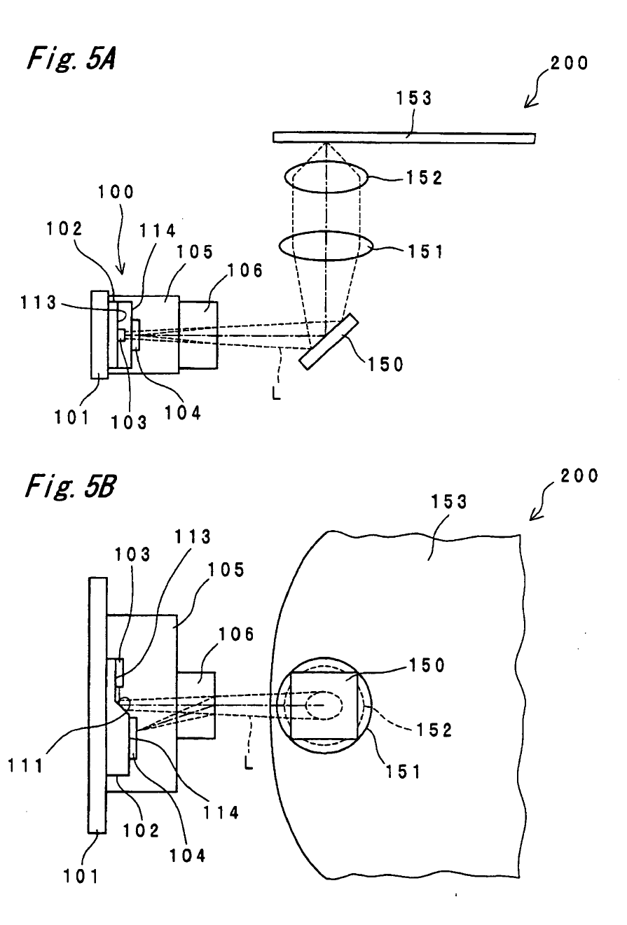

FIG. 5A schematically shows main parts of an optical pickup device 200 incorporating the semiconductor laser device 100, as viewed sideways. FIG. 5B is a schematic view of the optical pickup device 200 as viewed from below. It is noted that the cap 5 is partly removed in FIGS. 5A and 5B.

The optical pickup device 200 includes a semiconductor laser device 100, a collimator lens 151 placed in an optical path between the semiconductor laser device 100 and an optical disc 153, an objective lens 152 placed in an optical path between the collimator lens 151 and the optical disc 153, and a raising mirror 150 placed in an optical path between the collimator lens 151 and the semiconductor laser device 100.

The raising mirror 150 is inclined at an angle of 45° with respect to an optical axis of laser light L emitted from the semiconductor laser device 100. As a result of this, the raising mirror 150 changes the direction of the optical axis of the laser light L emitted from the semiconductor laser device 100 by 90°.

According to the optical pickup device 200 of this construction, the laser light L emitted from the semiconductor laser element 103 is changed in its optical axis direction by 90° by the raising mirror 111, then passes through the holographic element 106, and is further changed in its optical axis direction by 90° by the raising mirror 150, collimated by the collimator lens 151, and condensed onto a recording surface of the optical disc 153 by the objective lens 152. The light reflected by the recording surface of the optical disc 153 passes through the objective lens 152, the collimator lens 151 and the raising mirror 150 successively, and then is diffracted by the holographic element 106 so as to be led to the light receiving element 104. Thus, the light receiving element 104 outputs an electric signal corresponding to the reflected light. Information of the recording surface of the optical disc 153 is obtained based on the electric signal.

In this embodiment, the semiconductor laser device 100 is positioned such that the first and second mounting surfaces 113, 114 are generally vertical to the recording surface of the optical disc 153. However, the semiconductor laser device 100 may also be positioned such that the first and second mounting surfaces 113, 114 are generally parallel to the recording surface of the optical disc 153. With the semiconductor laser device 100 positioned in this way, the mirror 150 may be eliminated, which allows the parts count to be reduced.

Although the wiring board 101 formed of the top-face printed board 121, the Cu plate 122 and the bottom-face printed board 123 is used in the above embodiment, it is also possible to use a wiring board whose body is formed of ceramics.

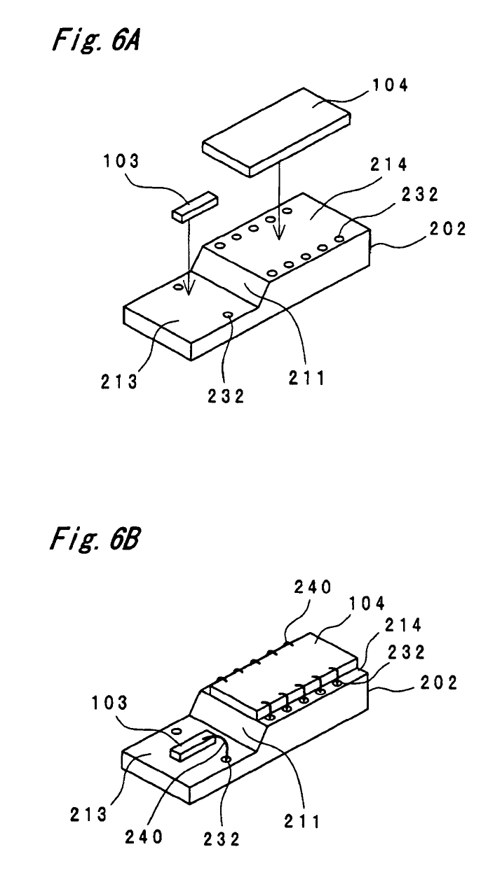

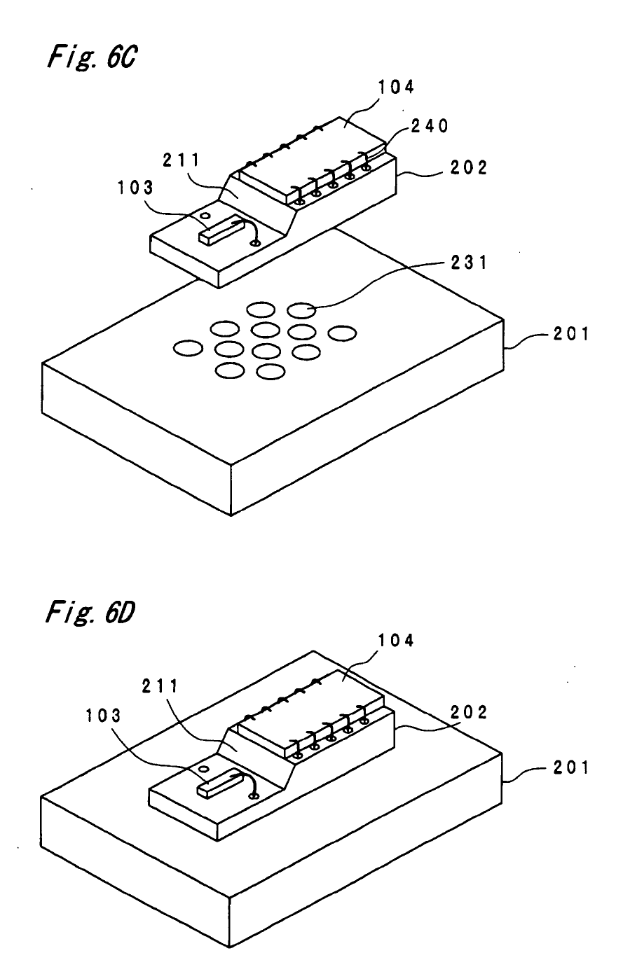

Also, as an example of the claimed block, the block 102 is mounted on the top face of the wiring board 101 in the above embodiment. Alternatively, as shown in FIGS. 6A to 6D, a block 202 may be mounted on a top face of a wiring board 201.

The way of mounting of the block 202 onto the top face of the wiring board 201 will be described below.

First, as shown in FIG. 6A, the semiconductor laser element 103 is mounted on a first mounting surface 213 of the block 202. The semiconductor laser element 103 is fixed to the first mounting surface 213 with a bond or a brazing material.

The block 202, which is formed of an insulator, has the first mounting surface 213, a second mounting surface 214, and a raising mirror 211 as an example of the mirror part. The first and second mounting surfaces 213, 214 have electrode portions 232, respectively. Although not shown, electrode portions are provided also on the bottom face of the block 202. The electrode portions of the bottom face of the block 202 are electrically connected to the electrode portions 232 of the top face of the block 202 via wiring patterns within the block 202. The first mounting surface 213 is generally parallel to the second mounting surface 214. The raising mirror 211 is inclined at an angle of about 45° with respect to the first mounting surface 213 and the second mounting surface 214. As a result of this, the raising mirror 211 is enabled to change the direction of the optical axis of the laser light L by about 90°.

Next, the light receiving element 104 is mounted on the second mounting surface 214 of the block 202. The light receiving element 104 is fixed to the second mounting surface 214 also with a bond or a brazing material.

Next, as shown in FIG. 6B, the input/output terminals of the semiconductor laser element 103 and the light receiving element 104 are connected to the electrode portions 232 at the top face of the block 202 via wires 240.

Next, as shown in FIG. 6C, the block 102 mounted with the semiconductor laser element 103 and the light receiving element 104 is mounted on top of the wiring board 201 with a bond or the like.

Electrode portions 231 as an example of the wiring patterns are placed on the top face of the wiring board 201 in positions in correspondence with the electrode portions at the bottom face of the block 202. As a result of this, when the block 202 is mounted on the top face of the wiring board 201, the electrode portions at the bottom face of the block 202 are electrically connected to the electrode portions 231 at the top face of the wiring board 201. Therefore, electric currents can be fed to the semiconductor laser element 103 via the pad-pattern electrode portions 231, and moreover signals detected by the light receiving element 104 can be extracted outside via the electrode portions 231.

After that, performing processes similar to those of FIGS. 4E and 4F leads to completion of a semiconductor laser device of another embodiment of the invention.

It is noted that the structure of the wiring board 201 is similar to that of the wiring board 101, except for the electrode portions 231. That is, the wiring board 201 is composed of a Cu plate, a top-face printed board placed on the Cu plate, and a bottom-face printed board placed under the Cu plate. The Cu plate has through-holes, and electrode portions are provided at the bottom face of the wiring board 101 (bottom face of the bottom-face printed board) at the specified intervals. These electrode portions are connected to the electrode portions 231 via the through-holes of the Cu plate.

The block 102 and its modification examples will be described below.

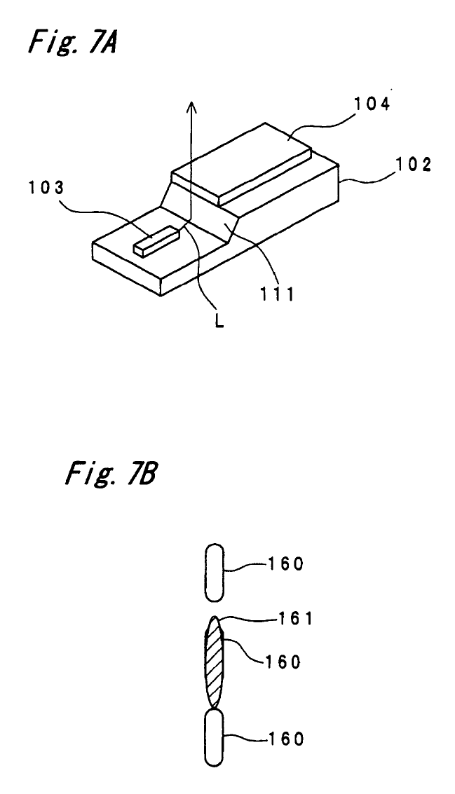

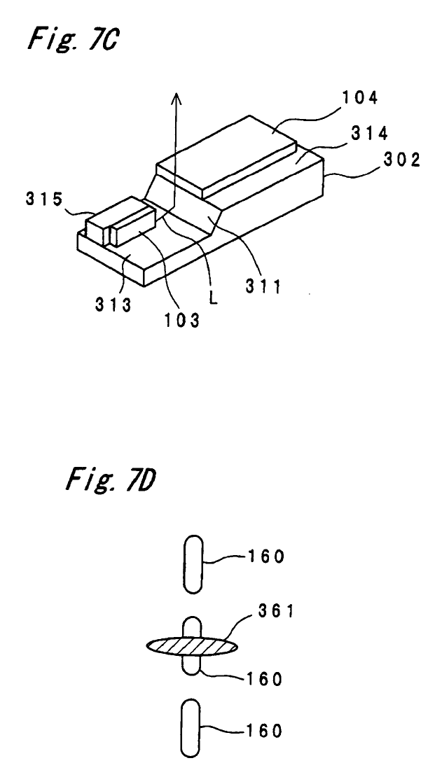

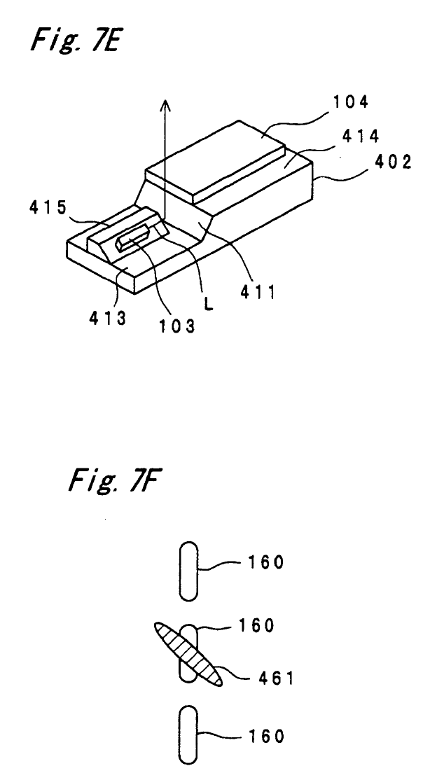

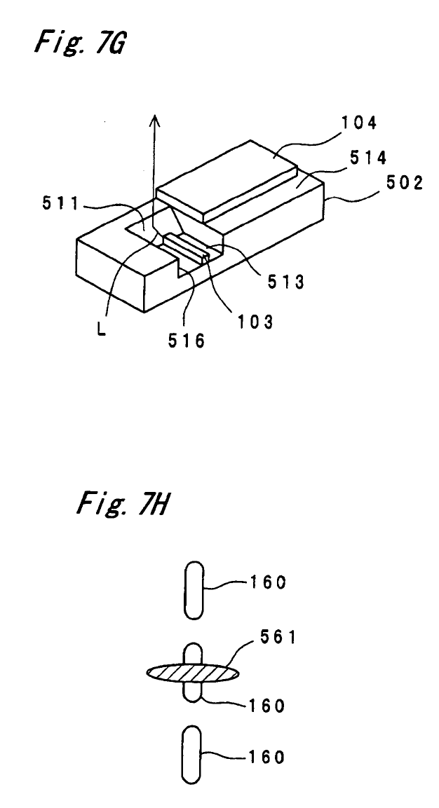

The block 102 of FIG. 7A is the one used in the above embodiment, where the direction of the optical axis of the laser light L emitted from the semiconductor laser element 103 is changed by about 90° by the raising mirror 111.

The laser light L whose optical axis direction has been changed by the raising mirror 111 is applied to the recording surface of an optical disc having pits 160, as shown in FIG. 7B. Then, an elliptical beam spot 161 is formed on the recording surface of the optical disc by the laser light L. The major axis of the beam spot 161 is generally parallel to or coincides with the direction in which the pits 160 are arrayed.

A block 302 of FIG. 7C is to carry the semiconductor laser element 103 on its first mounting surface 313. The semiconductor laser element 103 is fixed on a side face of a submount 315 which is provided independent of the block 302. The side face of the submount 315 is generally vertical to the first and second mounting surfaces 313, 314. Further, the first mounting surface 313 is generally parallel to the second mounting surface 314. That is, the first mounting surface 313 and the second mounting surface 314 are oriented so as to face in the same direction. Besides, a raising mirror 311 for reflecting the laser light L emitted from the semiconductor laser element 103 is provided on the block 302. The raising mirror 311 is inclined at an angle of about 45° with respect to the optical axis of the laser light L. As a result of this, the raising mirror 311 is enabled to change the direction of the optical axis of the laser light L by about 90°. It is noted that the block 302 is formed of an insulator.

The laser light L whose optical axis direction has been changed by the raising mirror 311 is, as shown in FIG. 7D, applied to the recording surface of the optical disc having pits 160. Then, an elliptical beam spot 361 is formed on the recording surface of the optical disc. The major axis of the beam spot 361 intersects at an angle of about 90° with the direction in which the pits 160 are arrayed.

A block 402 of FIG. 7E carries the semiconductor laser element 103 on its first mounting surface 413. The semiconductor laser element 103 is fixed on a side face of a submount 415 which is provided independent of the block 402. The side face of the submount 415 is inclined at an angle of about 45° with respect to the first and second mounting surfaces 413, 414. Further, the first mounting surface 413 is generally parallel to the second mounting surface 414. That is, the first mounting surface 413 and the second mounting surface 414 are oriented in the same direction. Besides, a raising mirror 411 for reflecting the laser light L emitted from the semiconductor laser element 103 is provided on the block 402. The raising mirror 411 is inclined at an angle of about 45° with respect to the optical axis of the laser light L. As a result of this, the raising mirror 411 is enabled to change the direction of the optical axis of the laser light L by about 90°. The block 402 is formed of an insulator.

The laser light L having an optical axis of which the direction has been changed by the raising mirror 411 is, as shown in FIG. 7F, applied to the recording surface of the optical disc having the pits 160. Then, an elliptical beam spot 461 is formed on the recording surface of the optical disc. The major axis of the beam spot 461 intersects at an angle of about 45° with the direction in which the pits 160 are arrayed.

A block 502 of FIG. 7G carries the semiconductor laser element 103 on its first mounting surface 513. The first mounting surface 513 is a bottom face of a recessed portion 516 provided in the block 502. Also, the first mounting surface 513 is generally parallel to a second mounting surface 514 on which the light receiving element 104 is mounted. That is, the first mounting surface 513 and the second mounting surface 514 are oriented so as to face in the same direction. Besides, a raising mirror 511 for reflecting the laser light L emitted from the semiconductor laser element 103 is provided on the block 502. The raising mirror 511 is inclined at an angle of 45° with respect to the optical axis of the laser light L. As a result of this, the raising mirror 511 is enabled to change the direction of the optical axis of the laser light L by about 90°. It is noted that the raising mirror 511 forms part of inner wall surfaces of the recessed portion 516. The block 502 is formed of an insulator.

The laser light L having an optical axis of which the direction has been changed by the raising mirror 511 is, as shown in FIG. 7H, applied to the recording surface of the optical disc having the pits 160. Then, an elliptical beam spot 561 is formed on the recording surface of the optical disc. The major axis of the beam spot 561 intersects at an angle of about 90° with the direction in which the pits 160 are arrayed.

The reason why the beam spots 161, 361, 461, 561 have an elliptical shape is that a far-field pattern of the semiconductor laser element 103 is elliptical.

As compared to the case where the block 102 is used in the optical pickup device, attenuation and variations in light intensity of reflected light due to birefringence on the recording surface of the optical disc are lessened when the block 302 or 502 is used in the optical pickup device, so that the quantity of received light of the light receiving element 104 is stabilized. Thus, the S/N (Signal-to-Noise) ratio can be improved.

As compared with the cases where the block 302 or 502 is used in the optical pickup device, attenuation and variations in light intensity of reflected light due to birefringence on the recording surface of the optical disc are lessened when the block 402 is used in the optical pickup device, so that the quantity of received light of the light receiving element 104 is stabilized. Thus, the S/N (Signal-to-Noise) ratio can be improved.

That is, the blocks 302, 502 are higher in S/N ratio improving effect than the block 102, and the block 402 is higher in S/N ratio improving effect than the blocks 302, 502.

Further, when the semiconductor laser device having the block 402 is used in the optical pickup device 200, the numerical aperture of the objective lens 152 is set larger than that of the collimator lens 151.

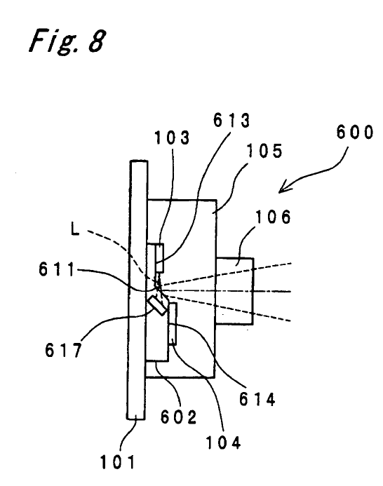

In the above described embodiment, the semiconductor laser device 100 is incorporated in the optical pickup device 200. Alternatively, a semiconductor laser device 600 shown in FIG. 8 may be incorporated in the optical pickup device 200.

The semiconductor laser device 600 includes a block 602 which internally contains a light receiving element 617 as an example of the second light receiving element.

The block 602, which is formed of an insulator, has a first mounting surface 613, a second mounting surface 614 and a raising half mirror 611. The raising half mirror 611 is inclined at an angle of 45° with respect to the optical axis of laser light L emitted from the semiconductor laser element 103. The raising half mirror 611 is an example of the claimed half mirror part.

The first mounting surface 613 carries the semiconductor laser element 103, and the second mounting surface 614 carries the light receiving element 104. Also, the first mounting surface 613 is generally parallel to the second mounting surface 614. That is, the first mounting surface 613 and the second mounting surface 614 face in the same direction. The first and second mounting surfaces 613, 614 are generally parallel to the top face of the wiring board 101.

According to the semiconductor laser device 600 of this construction, part of the laser light L emitted from the semiconductor laser element 103 is transmitted by the raising half mirror 611 to be incident on the light receiving element 617, while the rest of the laser light L is reflected by the raising half mirror 611. Since part of the laser light L is received by the light receiving element 617, the quantity of light to be outputted by the semiconductor laser element 103 can be controlled and maintained constant on the basis of an electric signal outputted by the light receiving element 617. Consequently, optical output control over the semiconductor laser element 103 can be implemented.

Instead of the raising half mirror 611, a raising half mirror having a membrane having a polarization property may also be used. That is, a raising half mirror for reflecting only one of p wave or s wave of the laser light L may be used instead of the raising half mirror 611.

The constitution of the semiconductor laser device of the present invention can be applied to dual-wavelength semiconductor laser devices. When the constitution of the semiconductor laser device of the present invention is applied to a dual-wavelength semiconductor laser device, a first semiconductor laser element for emitting laser light of a first wavelength and a second semiconductor laser element for emitting laser light of a second wavelength different from the first wavelength are mounted on the first mounting surface of the block.

Although in the above embodiments, the submounts 315, 415 are provided independently of the blocks 302, 402, namely, as different pieces from the blocks, yet the submounts 315, 415 may also be formed by integral molding with the blocks 302, 402.

The Cu plate 122 is used in the above embodiment. However, it is also possible to use ceramic plates or other metallic plates of good heat dissipation property instead of the Cu plate 122. That is, the heat sink of the present invention may be a ceramic plate or any other metallic plate which has a good heat dissipation property.

Embodiments of the invention being thus described, it will be obvious that the same may be varied in many ways. Such variations are not to be regarded as a departure from the spirit and scope of the invention, and all such modifications as would be obvious to one skilled in the art are intended to be included within the scope of the following claims.

What is claimed is:

1. A semiconductor laser device comprising:
a wiring board having wiring patterns on at least one surface thereof;
a block mounted on the one surface of the wiring board, the block having first and second mounting surfaces both facing in an identical direction, and including a mirror part for changing an optical axis of light;
a semiconductor laser element mounted on the first mounting surface and emitting laser light; and
a first light receiving element mounted on the second mounting surface and receiving reflected light of the laser light.

2. The semiconductor laser device as claimed in claim 1, wherein
the mirror part changes the optical axis of light by about 90°.

3. The semiconductor laser device as claimed in claim 1, wherein
the wiring board comprises:
a heat sink having through-holes;
a first printed board placed on the heat sink; and
a second printed board placed under the heat sink and connecting to the first printed board via the through-holes.

4. The semiconductor laser device as claimed in claim 1, wherein
the wiring board has a main body made of ceramics.

5. The semiconductor laser device as claimed in claim 1, further comprising
a cap which covers the block, the semiconductor laser element and the light receiving element.

6. The semiconductor laser device as claimed in claim 5, further comprising:
a holographic element placed on the cap for leading the reflected light to the light receiving element.

7. The semiconductor laser device as claimed in claim 1, wherein
a far-field pattern of the semiconductor laser element is an ellipse whose major axis is inclined at an angle of about 45° with respect to the second mounting surface.

8. The semiconductor laser device as claimed in claim 1, further comprising:
a second light receiving element which the laser light partially enters.

9. The semiconductor laser device as claimed in claim 8, wherein
the mirror part is a half mirror part, and
part of the laser light that has passed through the half mirror part enters the second light receiving element.

10. The semiconductor laser device as claimed in claim 9, wherein
the half mirror part has a polarization property.

11. The semiconductor laser device as claimed in claim 1, wherein
electrode portions of the semiconductor laser element and the light receiving element are connected to the wiring patterns via wires.

12. The semiconductor laser device as claimed in claim 1, wherein
the block is formed of an insulator.

13. An optical pickup device for performing reproduction, erasing, and/or recording of information on an optical disc, comprising:
the semiconductor laser device as defined in claim 1;
a collimator lens placed in an optical path between the semiconductor laser device and the optical disc; and
an objective lens placed in an optical path between the collimator lens and the optical disc.

14. The optical pickup device as claimed in claim 13, wherein
the first and second mounting surfaces are roughly parallel to a recording surface of the optical disc.

15. The optical pickup device as claimed in claim 13, wherein
the objective lens has a numerical aperture larger than a numerical aperture of the collimator lens.
